(19) United States
(12) Patent Application Publication
(10) Pub. No.: US 2012/0077295 A1
(43) Pub. Date: Mar. 29, 2012

(54) METHOD FOR DICING LED WAFER INTO MULTIPLE LED CHIPS

(75) Inventors: CHIA-HUI SHEN, Hukou Shiang (TW); TZU-CHIEN HUNG, Hukou Shiang (TW)

(73) Assignee: ADVANCED OPTOELECTRONIC TECHNOLOGY, INC., Hsinchu Hsien (TW)

(21) Appl. No.: 13/095,728

(22) Filed: Apr. 27, 2011

(30) Foreign Application Priority Data
Sep. 29, 2010 (CN) 201010297409.6

(51) Int. Cl. H01L 21/78

(52) U.S. Cl. 438/33; 257/E21.599

(57) ABSTRACT

A method for dicing an LED (light emitting diode) wafer into multiple LED chips includes steps: providing an LED wafer, the LED wafer comprising a substrate, a first semiconductor layer, a light-emitting layer, a second semiconductor layer, and a transparent, electrically conductive film; forming a first channel in the LED wafer extending downwardly through the transparent, electrically conductive film, the second semiconductor layer and the light-emitting layer to the first semiconductor layer, thereby exposing the first semiconductor layer; forming a second channel within the first channel, the second channel extending downwardly through the first semiconductor layer to the substrate, thereby exposing a top face of the substrate; forming a groove in the top face of the substrate within the second channel by means of laser cutting; and dicing the LED wafer along the groove.

### BACKGROUND

1. Technical Field

The present disclosure relates to a method for dicing an LED (light emitting diode) wafer into multiple LED chips.

2. Description of Related Art

As new type light source, LED chips are widely used in various applications. Generally, the LED chips are diced from an LED wafer by firstly mechanically forming a multipleity of grooves in the LED wafer. As the dimension of the LED chip is too small, positioning the grooves is difficult and time consuming, and has a risk of damaging the LED chip.

What is needed, therefore, is a method for dicing an LED wafer into multiple LED chips which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows a first step of a process for dicing an LED wafer into multiple LED chips in accordance with an exemplary embodiment of the present disclosure.

FIG. 2 shows a second step of the process for dicing the LED wafer into the multiple LED chips in accordance with the embodiment of the present disclosure.

FIG. 3 shows a third step of the process for dicing the LED wafer into the multiple LED chips in accordance with the embodiment of the present disclosure.

FIG. 4 shows a forth step of the process for dicing the LED wafer into the multiple LED chips in accordance with the embodiment of the present disclosure.

FIG. 5 shows a fifth step of the process for dicing the LED wafer into the multiple LED chips in accordance with the embodiment of the present disclosure.

FIG. 6 shows two LED chips formed in accordance with the embodiment, which are obtained after the fifth step shown in FIG. 5.

### DETAILED DESCRIPTION OF THE EMBODIMENTS

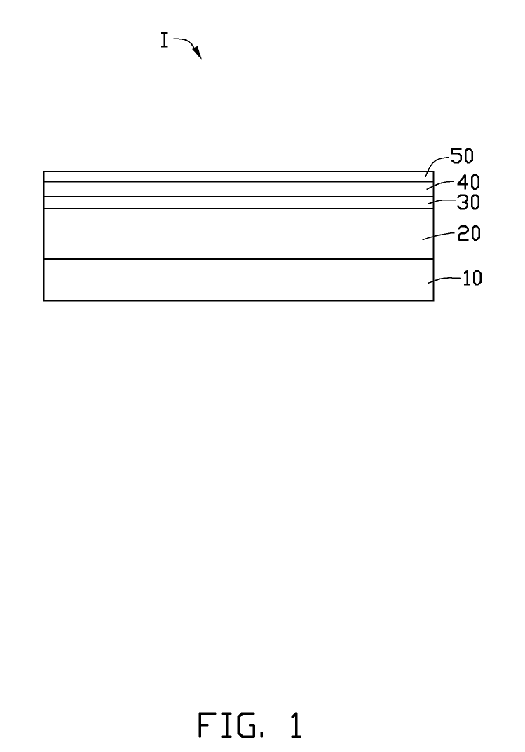

Referring to FIGS. 1-6, steps of a process for dicing an LED (light emitting diode) wafer I into multiple LED chips II in accordance with an exemplary embodiment of the present disclosure are illustrated.

Firstly, an LED wafer I is provided as shown in FIG. 1. The LED wafer I is a multilayer structure and comprises a substrate 10, a first semiconductor layer 20 formed on the substrate 10, a light-emitting layer 30 formed on the first semiconductor layer 20, a second semiconductor layer 40 formed on the light-emitting layer 30, and a transparent, electrically conductive film 50 formed on the second semiconductor layer 40. It can be understood that, the transparent, electrically conductive film 50 can be omitted; that is, the LED wafer I at least comprises a substrate 10, a first semiconductor layer 20 formed on the substrate 10, a light-emitting layer 30 formed on the first semiconductor layer 20, and a second semiconductor layer 40 formed on the light-emitting layer 30. The LED wafer I may be made of GaN, AlGaN, AlInGaN or other suitable light emitting materials. The substrate 10 may be made of sapphire, SiC, GaN or other suitable materials. In the embodiment of this disclosure, the first semiconductor layer 20 is an N-type semiconductor layer, and the second semiconductor layer 40 is a P-type semiconductor layer. The transparent, electrically conductive film 50 is made of tin doped indium oxide (ITO).

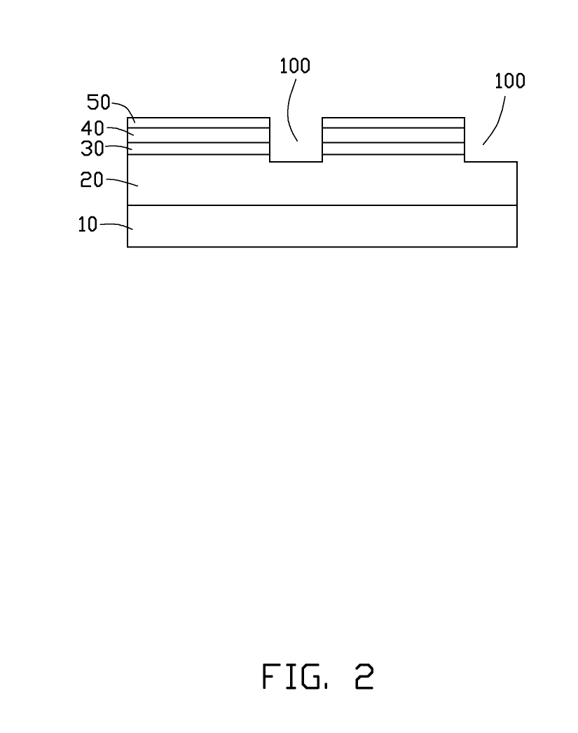

Referring to FIG. 2, a multipleity of first channels 100 are then defined in the LED wafer I in by means of etching, for example, chemical etching. The first channels 100 are evenly spaced from each other. The first channels 100 extend through the transparent, electrically conductive film 50, the second semiconductor layer 40 and the light-emitting layer 30, to a top portion of the first semiconductor layer 20, thereby exposing a portion of the first semiconductor layer 20 to an outer environment via the first channels 100.

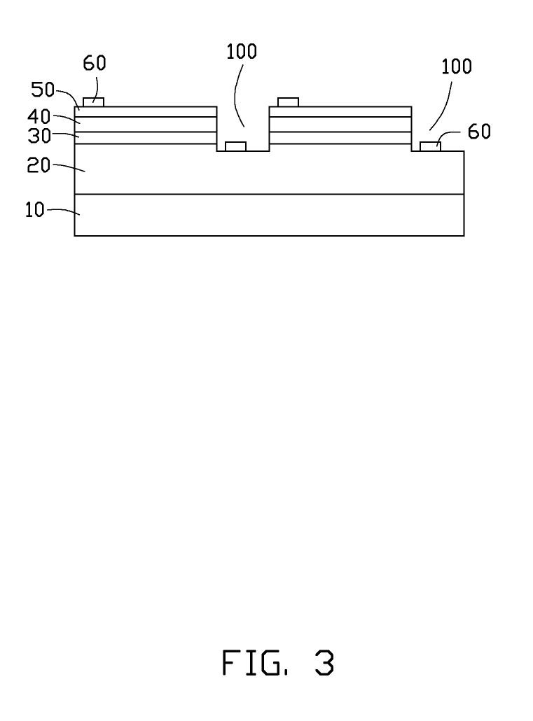

Referring to FIG. 3, in each of the areas that between two adjacent first channels 100, an electrode 60 is electrically disposed on the transparent, electrically conductive film 50, and in each of the first channels 100 another electrode 60 is electrically disposed on the exposed part of the first semiconductor layer 20.

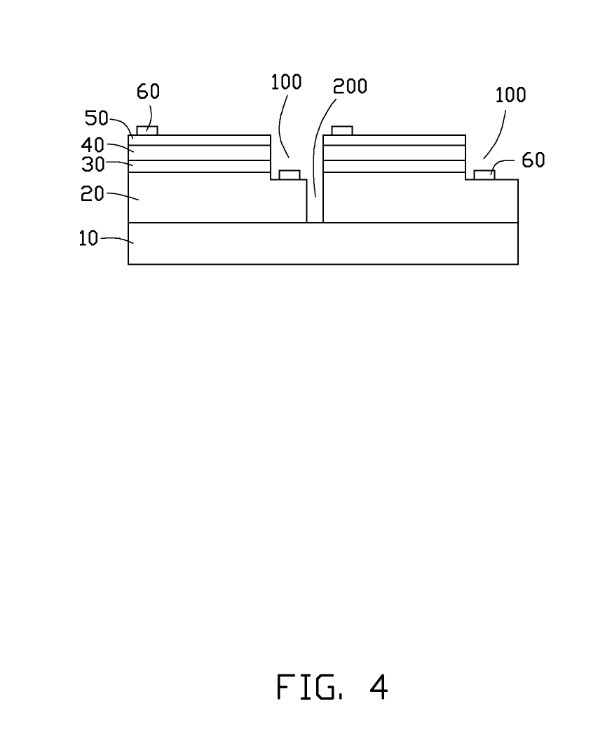

Referring to FIG. 4, a second channel 200 is defined through the first semiconductor layer 20 of the LED wafer I by means of etching, for example, chemical etching. The second channel 200 is below and communicates with a corresponding first channel 100. The second channel 200 is smaller than the corresponding first channel 100 in width, and is located besides and adjacent to the another electrode 60 in the corresponding first channel 100. The second channel 200 extends through the first semiconductor layer 20 to a top face of the substrate 10, thereby exposing a part of a top face of the substrate 10 to the outer environment.

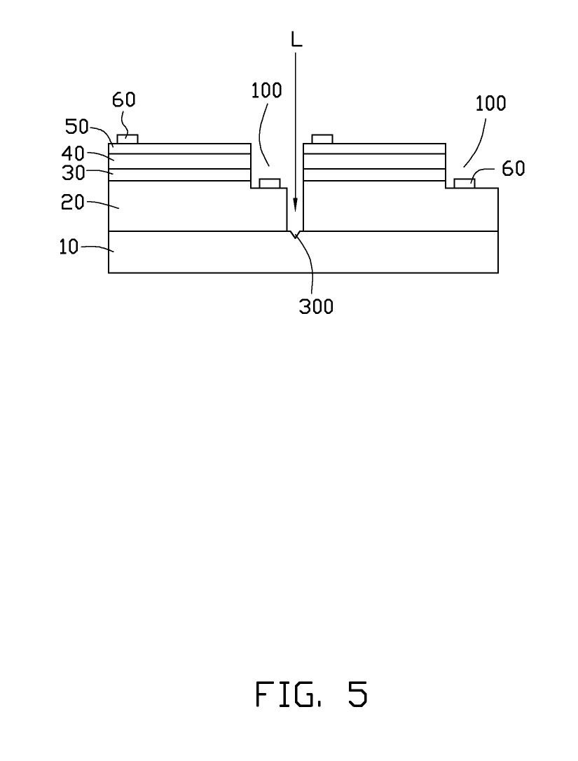

Referring to FIG. 5, a groove 300 is defined in the exposed top face of the substrate 10 corresponding to the second channel 200 by means of laser cutting. The groove 300 has a V-shaped cross-section. It can be understood that the electrodes 60 can be disposed on the LED wafer I after the step of forming the second channel 200, or the step of forming the groove 300.

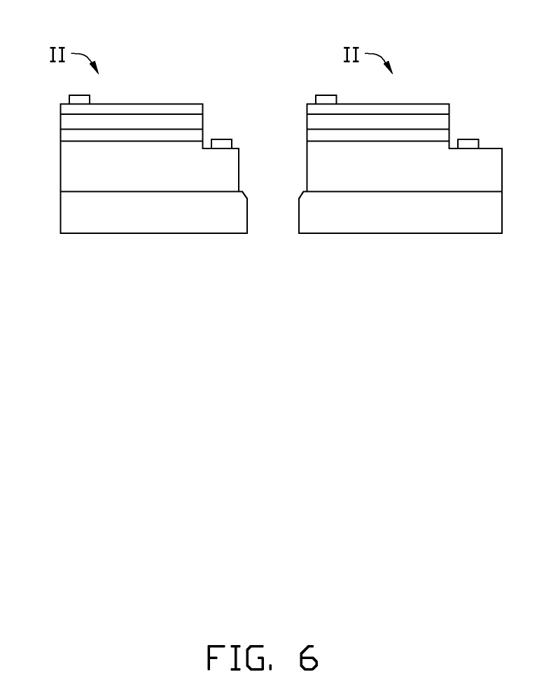

Finally, the wafer I is diced into a multipleity of individual LED chips II along the groove 300 as shown in FIG. 6. Because laser cutting has an advantage of speed and precision, the above process of dicing can simplify manufacturing processes of the LED chips II, thereby facilitating mass production of the LED chips II.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A method for dicing an LED (light emitting diode) wafer into multiple LED chips, comprising steps of:
providing an LED wafer, the LED wafer from bottom to top comprising a substrate, a first semiconductor layer formed on the substrate, a light-emitting layer formed on the first semiconductor layer, a second semiconductor layer formed on the light-emitting layer, and a transparent, electrically conductive film formed on the second semiconductor layer;
forming a first channel in the LED wafer, the first channel extending downwardly through the transparent conductive film, the second semiconductor layer and the light-emitting layer to the first semiconductor layer, thereby exposing the first semiconductor layer;
forming a second channel below and communicating with the first channel, the second channel extending downwardly through the first semiconductor layer to the substrate, thereby exposing a top face of the substrate, the second channel being narrower than the first channel;
forming a groove in the top face of the substrate corresponding to the second channel by means of laser cutting; and
dicing the LED wafer into multiple LED chips along the groove.

2. The method as claimed in claim 1, wherein the first channel is formed by means of etching.

3. The method as claimed in claim 1, wherein the second channel is formed by means of etching.

4. The method as claimed in claim 1, wherein the LED wafer is made of GaN, AlGaN, or AlInGaN.

5. The method as claimed in claim 4, wherein the first semiconductor layer is an N-type semiconductor layer.

6. The method as claimed in claim 4, wherein the second semiconductor layer is a P-type semiconductor layer.

7. The method as claimed in claim 1, wherein the substrate is made of sapphire, SiC, or GaN.

8. The method as claimed in claim 1 further comprising disposing an electrode on the transparent, electrically conductive film, and another electrode on the first semiconductor layer, after forming the second channel.

9. The method as claimed in claim 1 further comprising disposing an electrode on the transparent, electrically conductive film, and another electrode on the first semiconductor layer, after forming the groove.

10. A method for dicing an LED wafer into multiple LED chips, comprising steps of:
providing an LED wafer, the LED wafer from bottom to top comprising a substrate, a first semiconductor layer formed on the substrate, a light-emitting layer formed on the first semiconductor layer, and a second semiconductor layer formed on the light-emitting layer;
forming a first channel in the LED wafer, the first channel extending downwardly through the second semiconductor layer and the light-emitting layer, to the first semiconductor layer, thereby exposing the first semiconductor layer;
forming a second channel within the first channel, the second channel extending downwardly through the first semiconductor layer to the substrate, thereby exposing the substrate;
forming a groove in a top face of the substrate within the second channel by means of laser cutting; and
dicing the LED wafer along the groove.

11. The method as claimed in claim 10, wherein the first channel is formed by means of etching.

12. The method as claimed in claim 10, wherein the second channel is formed by means of etching.

13. The method as claimed in claim 10, wherein the LED wafer is made of GaN, AlGaN, or AlInGaN.

14. The method as claimed in claim 13, wherein the first semiconductor layer is an N-type semiconductor layer.

15. The method as claimed in claim 13, wherein the second semiconductor layer is a P-type semiconductor layer.

16. The method as claimed in claim 10, wherein the substrate is made of sapphire, SiC, or GaN.

17. The method as claimed in claim 10 further comprising disposing an electrode on the second semiconductor layer, and another electrode on the first semiconductor layer, after forming the second channel.

18. The method as claimed in claim 10 further comprising disposing an electrode on the second semiconductor layer, and another electrode on the first semiconductor layer, after forming the groove.

19. The method as claimed in claim 10, wherein the second channel is narrower than the first channel.
